(19) United States
(12) Patent Application Publication
(10) Pub. No.: US 2007/0085554 A1
(43) Pub. Date: Apr. 19, 2007

(54) Replaceable modular probe head

(75) Inventors: Hsiang-Ming Huang, Tainan (TW); An-Hong Liu, Tainan (TW); Yi-Chang Lee, Tainan (TW); Yao-Jung Lee, Tainan (TW); Yeong-Her Wang, Tainan (TW)

Correspondence Address: TROXELL LAW OFFICE PLLC, SUITE 1404, 5205 LEESBURG PIKE, FALLS CHURCH, VA, 22041, US

(73) Assignees: ChipMOS TECHNOLOGIES (Bermuda) LTD.; ChipMOS TECHNOLOGIES INC.

(21) Appl. No.: 11/249,464

(22) Filed: Oct. 14, 2005

(51) Int. Cl. G01R 31/02

(52) U.S. Cl. 324/754

(57) ABSTRACT

A replaceable modular probe head is composed of a plurality of in-parallel probing modules. Each probing module has a plurality of in-series probing regions. In the present embodiment, each probing module has mechanical connection parts on its both ends to attach to a printed circuit board (PCB) to be a multi-DUT probe card. Therefore, the probing module can be replaced individually when probes are damaged or worn without replacing the whole probe head to reduce the fabrication cost of a multi-DUT probe head.

### FIELD OF THE INVENTION

The present invention relates to a multi-DUT (Device Under Test) probe head, and more particularly, to a replaceable multi-DUT modular probe head.

### BACKGROUND OF THE INVENTION

Multi-DUT probe head is the major trend in the development of probe cards. When probing a wafer, a probe card after alignment will touch a plurality of integrated circuits, ICs, to reduce the movement and alignment of a probe card, i.e., to increase the throughput of a tester. Especially, a full-wafer contact probe card is an excellent multi-DUT probe card which can electrically contact all the bonding pads of all the chips on a wafer. However, since every probe on the multi-DUT probe head has to be good without any defeats, therefore, 100% yield requirement become the major technical bottlenecks in manufacturing multi-DUT probe head. Thus, higher cost is expected.

A conventional multi-DUT probe card, as shown in FIG. 1, comprises a multi-DUT probe head 10 and a circular printed circuit board 20 which is installed in the test head of a tester (not shown in the figure). The multi-DUT probe head 10 is a multi-layer circuit substrate which may be made of ceramic, polymer, or semiconductor. Moreover, the multi-DUT probe head 10 has a plurality of chip probing regions 11 defined and formed in an array corresponding to a plurality of untested chips on a wafer. A plurality of probes 12 are disposed on each chip probing region 11 to probe a plurality of bonding pads of the corresponding untested chip. However, when manufacturing a probe head 10, if there is only one defect in a single probe or in a single trace, the multi-DUT probe head 12 has to be discarded. Moreover, during chip probing, as long as one of the probes is damaged or worn, then the whole multi-DUT probe head 12 has to be replaced. Therefore, a multi-DUT probe head is very expensive with many operation restrictions or it can be easily damaged.

### SUMMARY OF THE INVENTION

The main purpose of the present invention is to provide a replaceable modular probe head which is composed of a plurality of in-parallel probing modules. Each probing module has a plurality of in-series probing regions for disposing probes. Therefore, each probing module can be individually replaced without replacing or discarding the whole probe head leading to lower costs in manufacturing of multi-DUT probe heads.

The second purpose of the present invention is to provide a replaceable modular probe head where each probing module has mechanical connection parts at both ends such as downsets with through holes to mechanically attach to a multi-layer printed circuit board of a probe card for the replacement of individual probing modules.

According to the present invention, a replaceable modular probe head comprises a plurality of in-parallel probing modules. Each probing module has a plurality of in-series probing regions for disposing probes.

### DESCRIPTION OF THE DRAWINGS

FIG. 1 is a top view of a conventional multi-DUT probe head installed as a probe card.

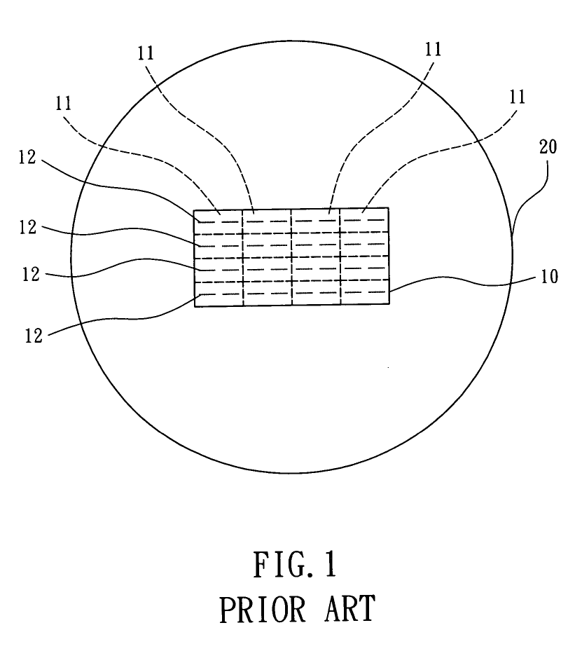

FIG. 2 is the top view of a replaceable modular probe head installed on a probe card PCB according to the embodiment of the present invention.

FIG. 3 is the three-dimensional view of the replaceable modular probe head before assembly according to the embodiment of the present invention.

### DETAIL DESCRIPTION OF THE INVENTION

Please refer to the attached drawings, the present invention will be described by means of embodiment(s) below.

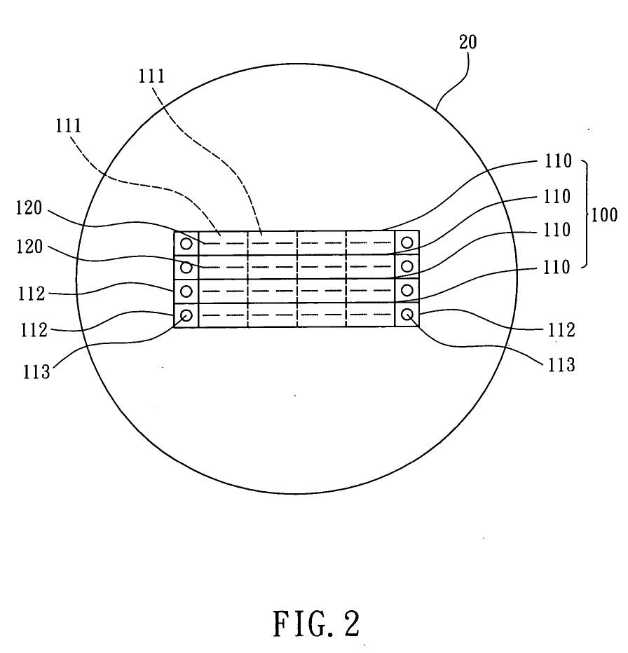

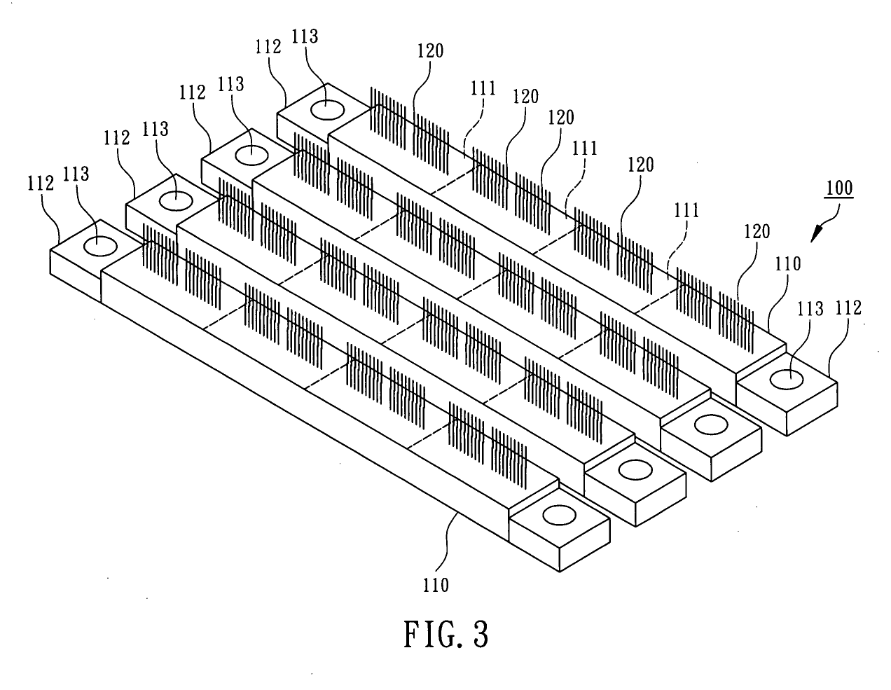

According to the embodiment of the present invention, a replaceable modular probe head is revealed in FIG. 2 and FIG. 3. A replaceable probe head 100 comprises a plurality of probing modules 110 for disposing a plurality of probes 120 where the probing modules 110 are disposed in parallel as shown in FIG. 3, to individually fix to a probe card PCB. The probing modules 110 can be made of ceramic, polymer, or semiconductor. Each probing module 110 has a plurality of in-series probing regions 111 corresponding to a plurality of untested ICs on a wafer, not shown in the figure. A plurality of probes 120 are disposed on each probing region 111. In the embodiment of the present invention, probes 120 are flexible probes fabricated by MEMS processes. The plurality of probes in all the probing regions 111 are disposed in a same pattern. Therefore, the probing modules 110 are individually fabricated and then assembled to be the replaceable modular probe head 100 to reduce the fabrication cost of multi-DUT probe head. Moreover, the replaceable modular probe head 100 can further be implemented in a full-wafer contact probe card.

Each probing module 110 has a plurality of mechanical connection parts 112 at both ends as shown in FIG. 3. In the embodiment of the present invention, the mechanical connection parts 112 are downsets with through holes 113 so that the probing modules can be mechanically attached to the printed circuit board 20, an electrical medium, or an interposer of the probe head by screws through the through holes 113. Therefore, each probing module 110 can be individually attached to the printed circuit board 20. Moreover, each probing module 110 can be individually replaced.

Therefore, when the replaceable modular probe head 100 is attached to a printed circuit board 20, or an electrical interface board, or an interposer to be a probe card, the probing regions 111 of the probing modules 110 can be disposed in array. During chip probing, the plurality of probes 120 disposed on the probing regions 111 can probe a plurality of bonding pads of a plurality of untested chips to achieve multi-DUT probing. Furthermore, when some of the probes 120 are damaged or worn, only the probing module 110 of the damaged or worn probes 120 is replaced without discarding the whole probe head.

The above description of embodiments of this invention is intended to be illustrative and not limiting. Other embodiments of this invention will be obvious to those skilled in the art in view of the above disclosure.

1-7. (canceled)

8. A replaceable modular probe head comprising:
a) a printed circuit board and
b) a plurality of in-parallel probing modules positioned in parallel and removably connected to the printed circuit board, each of the plurality of in-parallel probing modules engaging at least one adjacent probing module of the plurality of in-parallel probing modules, each of the plurality of in-parallel probing modules having:
i) a plurality of in-series probing regions, a predetermined number of in-series probing regions of the plurality of in-series probing regions are positioned in series along a length of each of the plurality of in-parallel probing modules; and
ii) a plurality of probes, a predetermined number of probes of the plurality of probes are located on each of the plurality of in-series probing regions,
wherein the plurality of probes located on each of the plurality of in-parallel probing modules are positioned in at least one parallel line along a length of each of the plurality of in-parallel probing modules.

9. The replaceable modular probe head according to claim 8, wherein each of the plurality of in-parallel probing modules has a mechanical connection part located at each of two opposing ends thereof.

10. The replaceable modular probe head according to claim 9, wherein each mechanical connection part is a downset having a through hole.

11. The replaceable modular probe head according to claim 9, wherein each mechanical connection part is individually connected to the printed circuit board.

12. The replaceable modular probe head according to claim 8, wherein the plurality of probes located on each of the plurality of in-parallel probing modules are positioned in a common pattern.

13. The replaceable modular probe head according to claim 8, wherein each of the plurality of probes are flexible.

14. The replaceable modular probe head according to claim 8, wherein the replaceable modular probe head is a full-wafer contract probe head.
